(19) United States
(12) Patent Application Publication
(10) Pub. No.: US 2025/0364393 A1
(43) Pub. Date: Nov. 27, 2025

(54) SEMICONDUCTOR PACKAGE AND METHOD OF FORMING THE SAME

(71) Applicant: Taiwan Semiconductor Manufacturing Company, Ltd., Hsinchu (TW)

(72) Inventors: Hou-Ju Huang, Hsinchu County (TW); Chen-Hsuan Tsai, Taitung City (TW); Chin-Chuan Chang, Hsinchu County (TW); Ying-Ching Shih, Hsinchu City (TW)

(73) Assignee: Taiwan Semiconductor Manufacturing Company, Ltd., Hsinchu (TW)

(21) Appl. No.: 18/673,204

(22) Filed: May 23, 2024

(51) Int. Cl. H01L 23/498; H01L 21/304; H01L 23/00

(52) U.S. Cl. CPC H01L 23/49866; H01L 21/304; H01L 23/49844; H01L 24/08; H01L 24/32; H01L 24/80; H01L 24/83; H01L 2224/08225; H01L 2224/32225; H01L 2224/80895; H01L 2224/80896; H01L 2224/83895; H01L 2224/83896; H01L 2924/13067

(57) ABSTRACT

A semiconductor package includes an interposer, a semiconductor die and a first polymeric material. The interposer has an interposer bonding structure thereon, and a sidewall of the interposer bonding structure is flush with a sidewall of the interposer. The semiconductor die has a die bonding structure thereon, and a sidewall of the die bonding structure is recessed from a sidewall of the semiconductor die. The semiconductor die is bonded to interposer through the die bonding structure and the interposer bonding structure. The first polymeric material is disposed in a non-bond region between the semiconductor die and the interposer, and encompassed by the semiconductor die, the die bonding structure and the interposer bonding structure. The porosity of the first polymeric material is less than about 20% in the non-bond region between the semiconductor die and the interposer.

### BACKGROUND

In recent years, the semiconductor industry has experienced rapid growth due to continuous improvement in integration density of various electrical components, e.g., transistors, diodes, resistors, capacitors, etc. For the most part, this improvement in integration density has come from successive reductions in minimum feature size, which allows more components to be integrated into a given area. Although the existing integrated circuit packages or semiconductor packages have been generally adequate for their intended purposes, they have not been entirely satisfactory in all respects.

### BRIEF DESCRIPTION OF THE DRAWINGS

FIG. 1 is a simplified top view of a package assembly in accordance with some embodiments.

FIG. 2, FIG. 3, FIG. 4, FIG. 5A, FIG. 5B and FIG. 5C are schematic cross-sectional views of a method of forming a semiconductor package in accordance with some embodiments.

FIG. 6A, FIG. 6B and FIG. 6C are schematic cross-sectional views of semiconductor packages in accordance with some embodiments.

FIG. 7A, FIG. 7B and FIG. 7C are schematic cross-sectional views of semiconductor packages in accordance with some embodiments.

### DETAILED DESCRIPTION

The following disclosure provides many different embodiments, or examples, for implementing different features of the provided subject matter. Specific examples of components and arrangements are described below for the purposes of conveying the disclosure in a simplified manner. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the same or similar reference numerals and/or letters may be used to refer to the same or similar element in the various examples of the disclosure. The repeated use of the reference numerals is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein to facilitate the description of one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments described herein disclose semiconductor packages and forming methods thereof. A die usually has a chamfer portion due to the previous die cutting process. When the die with a chamfer portion is hybrid-bonded to the underlying interposer, a space is formed between the die and the interposer around the chamfer portion. A void may occur in the space after molding the die on the interposer, so the bonding performance is deteriorated, and the delamination and high coefficient of thermal expansion (CTE) caused by voids may occur at the bonding interface. In the disclosure, the space between the die and the interposer around the chamfer portion is first filled with a polymeric material with a smaller filler size, a lower viscosity and/or a higher thixotropic index, so as to improve the filling performance in the space between the die and the interposer around the chamfer portion. Thereafter, another polymeric material with a greater filler size, a higher viscosity and/or a lower thixotropic index is formed to encapsulate the die, so as to robust the package. By such manner, the bonding performance is improved and the package stiffness is obtained.

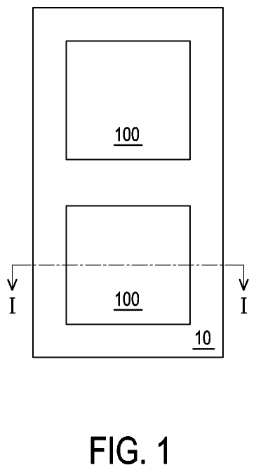

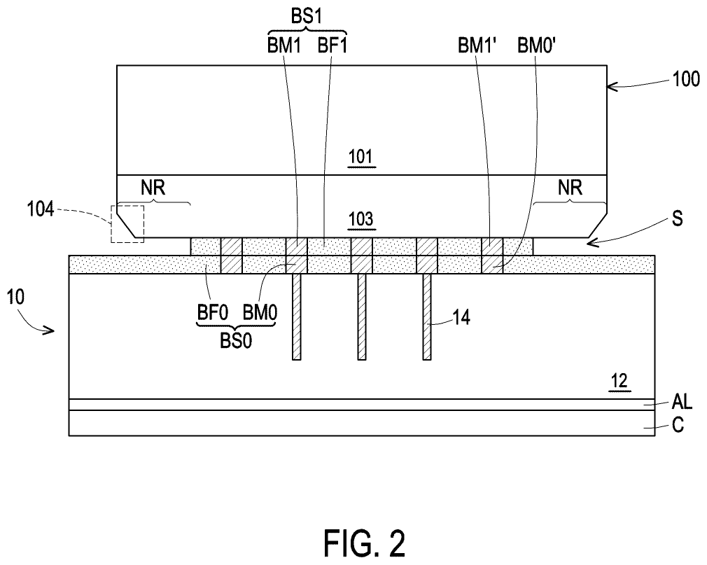

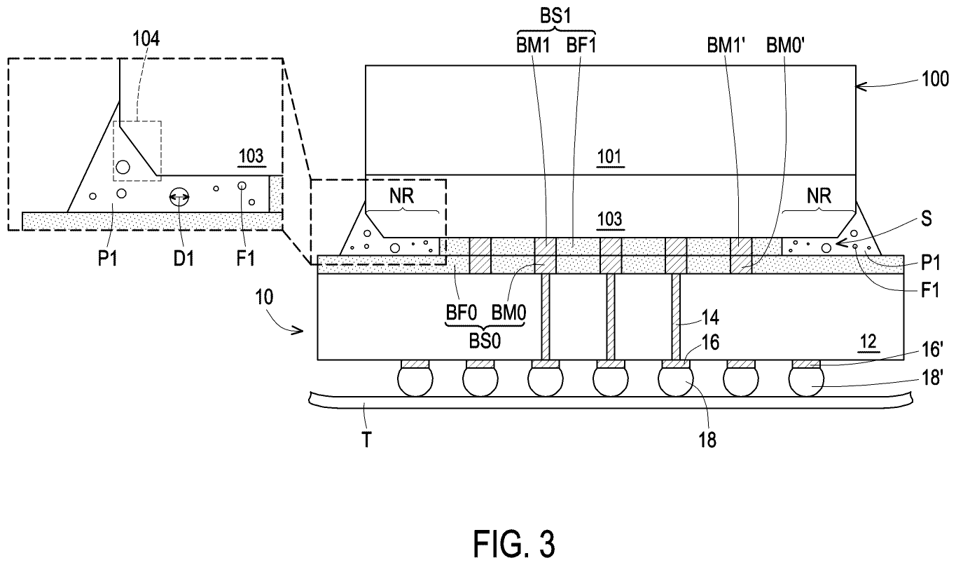

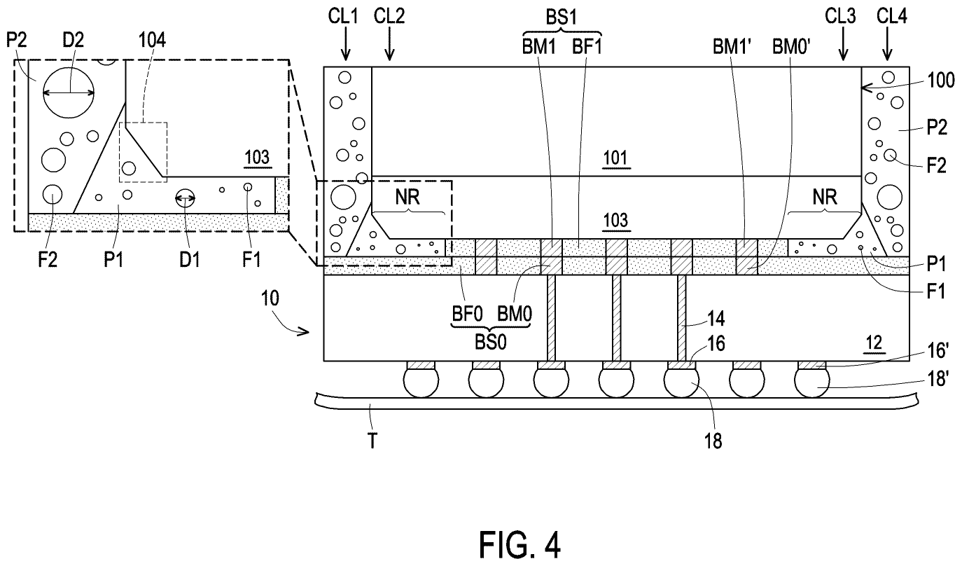

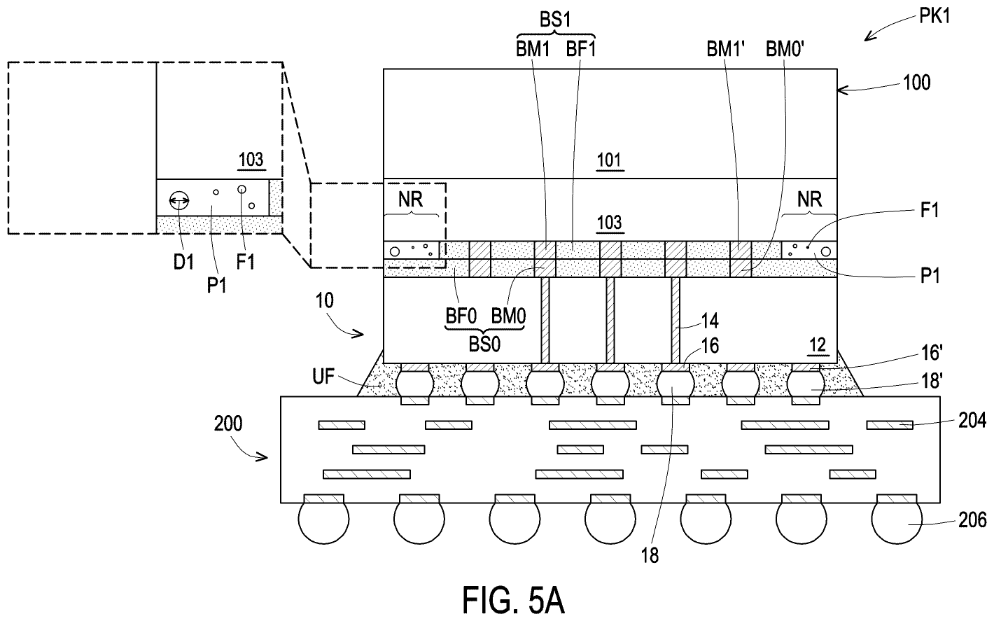

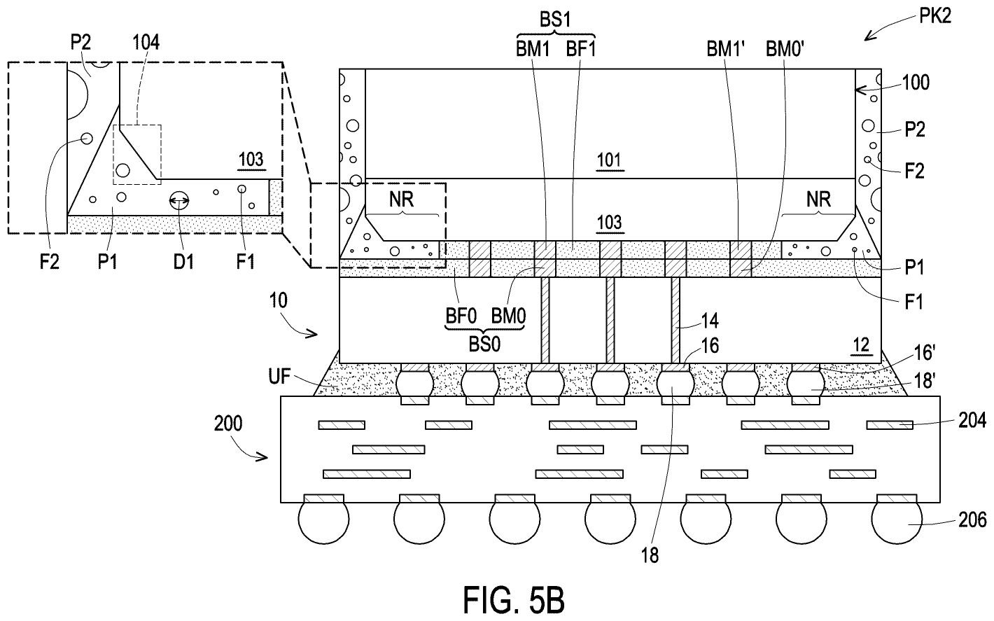

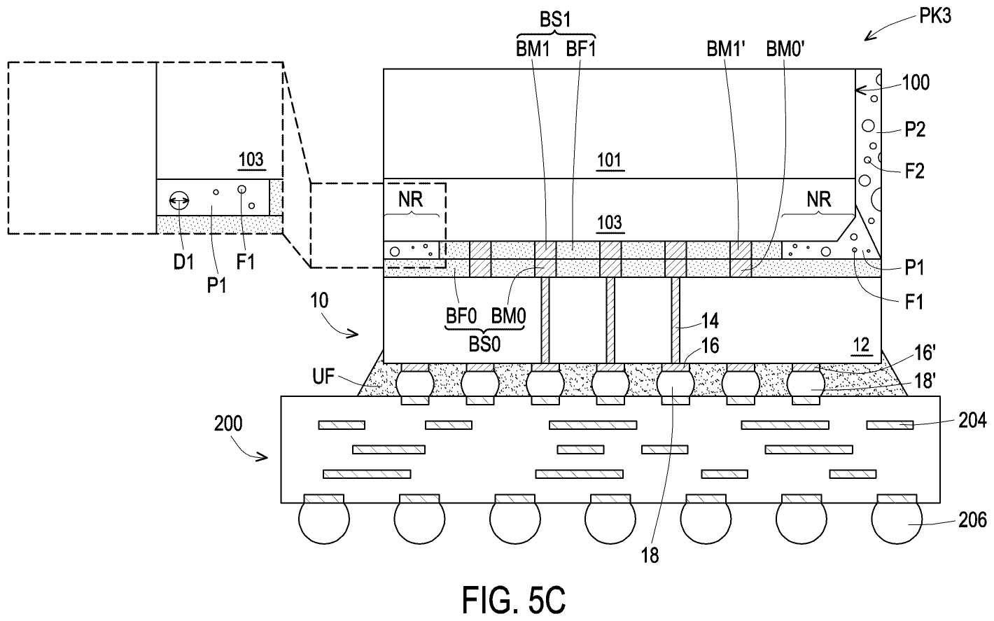

FIG. 1 is a simplified top view of a semiconductor package in accordance with some embodiments. For clarity and illustration purposes, only dies and interposer are shown in FIG. 1. In some embodiments, FIG. 2 to FIG. 5C are schematic cross-sectional views of a semiconductor package taken along the line I-I of FIG. 1. It is understood that the disclosure is not limited by the method described below. Additional operations can be provided before, during, and/or after the method and some of the operations described below can be replaced or eliminated, for additional embodiments of the methods. Although FIG. 2 to FIG. 5C are described in relation to a method, it is appreciated that the structures disclosed in FIG. 2 to FIG. 5C are not limited to such a method, but instead may stand alone as structures independent of the method.

Referring to FIG. 1 and FIG. 2, an interposer 10 is provided on a carrier C. In some embodiments, the carrier C includes a glass carrier or a ceramic carrier. In some embodiments, the carrier C has an adhesive layer AL thereon, and the interposer 10 is attached to the adhesive layer AL. The adhesive layer AL includes a light-to-heat-conversion (LTHC) film, or the like.

In some embodiments, the interposer 10 includes a substrate 12, and through vias 14 extending from one side to the opposite side of the substrate 12. In some embodiments, the interposer 10 is a silicon-containing interposer. The substrate 12 may include elementary semiconductor such as silicon, germanium and/or a compound semiconductor such as silicon germanium, silicon carbide, gallium arsenic, indium arsenide, gallium nitride or indium phosphide, and the through vias 14 may include metal such as copper and insulated from the semiconductor substrate 12 by insulating liners. In other embodiments, the interposer 10 is an organic interposer or a glass interposer. The substrate 12 may include a dielectric material, and the through vias 14 may include metal such as copper. The through vias 14 may not penetrate through the substrate 12 at this stage.

In some embodiments, the interposer 10 further includes an interposer bonding structure BS0 electrically connected to the through vias 14. In some embodiments, the sidewall of the interposer bonding structure BS0 is flush with the sidewall of the interposer 10. In some embodiments, the interposer bonding structure BS0 includes bonding metal features BM0 and BM0′ embedded in a bonding dielectric layer BF0. In some embodiments, the bonding dielectric layer BF0 includes silicon, silicon oxide, silicon nitride, silicon oxynitride, a polymer or a combination thereof. In some embodiments, the bonding metal features BM0 and BM0′ include bonding pads, bonding vias and combination thereof. The bonding metal features BM0 are active bonding metal features for providing electrical connection to an electrical component. The bonding metal features BM0′ are dummy bonding metal features at a floating potential for improving the bonding performance. The bonding metal features BM0 and BM0′ may include Cu, Ti, Ta, W, Ru, Co, Ni, a combination thereof or the like. In some embodiments, a seed layer and/or a barrier layer may be disposed between each bonding metal feature and the bonding dielectric layer. The seed layer may include Ti/Cu. The barrier layer may include Ta, TaN, Ti, TiN, CoW or a combination thereof.

In some embodiments, the interposer 10 is an active interposer that contains at least one functional device or integrated circuit device included on/in the substrate. Such active interposer is referred to as a “device-containing interposer” in some examples. In some embodiments, the functional device includes an active device, a passive device, or a combination thereof. The functional device includes, for example but not limited to, transistors, capacitors, resistors, diodes, photodiodes, fuse devices and/or other similar components. In other embodiments, the interposer 10 is a passive interposer, which is lack of a functional device or integrated circuit device. Such passive interposer is referred to as a “device-free interposer” in some examples.

Still referring to FIG. 1 and FIG. 2, one or more dies 100 are provided over and bonded to the interposer 10. The dies 100 may have the same or different functions and/or dimensions. Each semiconductor die 100 may be a logic die, a memory die, a CPU, a GPU, an xPU, a MEMS die, a SoC die, a photonic die or the like. The dimension may be a height, a width, a size, a top-view area or a combination thereof.

In some embodiments, the semiconductor die 100 includes a substrate 101 and a device layer 103. The substrate 101 may include elementary semiconductor such as silicon, germanium and/or a compound semiconductor such as silicon germanium, silicon carbide, gallium arsenic, indium arsenide, gallium nitride or indium phosphide. The substrate 101 may be doped as needed. The device layer 103 may include a transistor such as a fin field effect transistor (FinFET), a nanostructure FET (nano-FET) (e.g., a nanosheet transistor, a nanowire transistor or a gate-all-around transistor), a planar FET, the like, or a combination thereof. The device layer 103 may further include an interconnect structure electrically connected to the transistor, and a passivation layer covering the interconnect structure.

In some embodiments, the semiconductor die 100 has a chamfer portion 104 due to the previous die cutting process such as a laser grooving process. The chamfer portion 104 may have an inclined surface or curve surface with respect to the vertical sidewall of the semiconductor die 100. The chamfer portion 104 may be referred to as an “undercut portion” in some examples. In some embodiments, the chamfer portion 104 may be present at the level of the passivation layer and/or dielectric layer of the interconnect structure of the device layer 103.

In some embodiments, the semiconductor die 100 further includes a die bonding structure BS1 electrically connected to the interconnect structure of the device layer 103. In some embodiments, the die bonding structure BS1 includes bonding metal features BM1 and BM1′ embedded in a bonding dielectric layer BF1. In some embodiments, the bonding dielectric layer BF1 includes silicon, silicon oxide, silicon nitride, silicon oxynitride, a polymer or a combination thereof. In some embodiments, the bonding metal features BM1 and BM1′ include bonding pads, bonding vias and combination thereof. The bonding metal features BM1 are active bonding metal features for providing electrical connection to an electrical component. The bonding metal features BM1′ are dummy bonding metal features at a floating potential for improving the bonding performance. The bonding metal features BM1 and BM1′ may include Cu, Ti, Ta, W, Ru, Co, Ni, a combination thereof or the like. In some embodiments, a seed layer and/or a barrier layer may be disposed between each bonding metal feature and the bonding dielectric layer. The seed layer may include Ti/Cu. The barrier layer may include Ta, TaN, Ti, TiN, CoW or a combination thereof.

In some embodiments, in order to release the bonding interface stress, the bonding dielectric layer BF1 of the die bonding structure BS1 is partially removed by an etching process such as a shallow plasma dicing (SPD) process. Accordingly, the sidewall of the die bonding structure BS1 is recessed from the sidewall of the semiconductor die 100 by a non-zero distance.

Continue referring to FIG. 2, the semiconductor die 100 is bonded to the interposer 10 through a hybrid bonding including a metal-to-metal bonding and a dielectric-to-dielectric bonding. Specifically, the semiconductor die 100 is bonded to the interposer 10 through the die bonding structure BS1 and the interposer bonding structure BS0, in which the bonding metal features BM1 are connected to the bonding metal features BM0, the bonding metal features BM1′ are connected to the bonding metal features BM0′, and the bonding dielectric layer BF1 is connected to the bonding dielectric layer BF0. The semiconductor die 100 is bonded to the interposer 10, such that a space S is formed between the semiconductor die 100 and the interposer 10 in the non-bond region NR and encompassed by the semiconductor die 100, the die bonding structure BS1 and the interposer bonding structure BS0.

Referring to FIG. 3, a polymeric material P1 is formed between the semiconductor die 100 and the interposer 10 and fills in the space S in the non-bond region NR. The polymeric polymer P1 may be formed by dispensing, injecting, and/or spraying process. The polymeric material P1 may include any suitable material such as epoxy resin, phenol resin, thermally-set resin, polymide, polyamine, polynitrile, polyacrylate, polybenzoxazole (PBO), polyimide, benzocyclobutene (BCB), oxazole polymer, or the like. The polymeric material P1 may further include various fillers F1 with different sizes and shapes. The fillers may be included to improve adhesion, release stress, reduce coefficient of thermal expansion (CTE) mismatch, and the like. The fillers F1 may include oxide, nitride or carbide, such as silicon oxide, aluminum oxide, boron nitride, or the like. Other fillers which may be included for other purposes may also be used. The polymeric material P1 has specific properties such that the polymeric material P1 can fill in the space S to prevent voids from being formed between the semiconductor die 100 and the interposer 10 in the non-bond region NR. In some embodiments, the space S in the non-bond region NR is completely filled with the polymeric material P1; that is, the polymeric material P1 is void free in the non-bond region NR between the semiconductor die 100 and the interposer 10. However, the disclosure is not limited thereto. In other embodiments, the porosity of the polymeric material P1 is less than about 20%, 10% or 5% in the space S or in the non-bond region NR between the semiconductor die 100 and the interposer 10. The porosity of the polymeric material P1 is so small that the package stiffness is not affected.

In some embodiments, the polymeric material P1 has a maximum filler size D1 of about 10 um or less (e.g., 5 um or less), a thixotropic index of about 1.5 or more, and/or a viscosity of less than about 10 Pa·s, such that the polymeric material P1 can fill in the space S in a void-free or less-void manner. In some embodiments, the polymeric material P1 covers the chamfer portion 104 of the semiconductor die 100, and climbs onto the lower sidewall of the semiconductor die 100.

Referring to FIG. 4, a polymeric polymer P2 is formed over the interposer 10, laterally encapsulates the semiconductor die 100 and covers the polymeric polymer P1. The polymeric polymer P2 may be formed by a molding process followed by a curing process. The polymeric material P2 may include any suitable material such as epoxy resin, phenol resin, thermally-set resin, polymide, polyamine, polynitrile, polyacrylate, polybenzoxazole (PBO), polyimide, benzocyclobutene (BCB), oxazole polymer, or the like. The polymeric material P2 may further include various fillers F2 with different sizes and shapes. The fillers may be included to improve adhesion, release stress, reduce coefficient of thermal expansion (CTE) mismatch, and the like. The fillers F2 may include oxide, nitride or carbide, such as silicon oxide, aluminum oxide, boron nitride, or the like. Other fillers which may be included for other purposes may also be used. The polymeric material P2 and the polymeric material P1 may have different compositions and fillers for different purposes. The polymeric material P2 has specific properties such that the polymeric material P2 can strength the package structure. In some embodiments, the maximum filler size of the fillers F1 of the polymeric material P1 is different from (e.g., less than) the maximum filler size of the fillers F2 of the polymeric material P2. In some embodiments, the thixotropic index of the polymeric material P1 is different from (e.g., greater than) the thixotropic index of the polymeric material P2. In some embodiments, the viscosity of the polymeric material P1 is different from (e.g., less than) the viscosity of the polymeric material P2. In some embodiments, the polymeric material P2 has a maximum filler size D2 of greater than about 10 um, a thixotropic index of less than about 1.5, and/or a viscosity of greater than about 10Pa·s, such that the polymeric material P2 can stabilize the semiconductor package.

Still referring to FIG. 4, the substrate 12 of the interposer 10 is thinned, until the surfaces of the through vias 104 are exposed. The thinning process includes a polishing process, a grinding process or a combination thereof.

Thereafter, metal pads 16 and 16′ are formed on the side of the interposer 10 opposite to the semiconductor die 100. The metal pads 16 are active metal pads for providing electrical connection to an electrical component. The metal pads 16′ are dummy metal pads at a floating potential for improving the bonding performance. The metal pads 16 and 16′ may include Cu, Ti, Ta, W, Ru, Co, Ni, a combination thereof or the like.

Afterwards, bumps or connectors 18 and 18′ are formed on and electrically connected to the metal pads 16 and 16′, respectively. The connectors 18 are active metal connectors for providing electrical connection to an electrical component. The connectors 18′ are dummy metal connectors at a floating potential for improving the bonding performance. The connectors 18 and 18′ include solder bumps, and/or may include metal pillars (e.g., copper pillars), solder caps formed on metal pillars, and/or the like. The connectors 18 and 18′ are referred to as “controlled collapse chip connection (C4) bumps” in some examples.

Next, the intermediate wafer-level semiconductor structure including the interposer 10 and the underlying semiconductor die 100 is attached to a wafer tape T with the connectors 18 and 18′ facing the wafer tape T.

Still referring to FIG. 4, a wafer dicing process is performed to the wafer-level semiconductor structure, so as to separate adjacent semiconductor packages from each other. Specifically, a cutting process is performed to the wafer-level semiconductor structure along the cutting lines. The cutting process may be performed using a mechanical saw or the like. As shown in FIG. 4, due to the process variation of the cutting process, one side of each semiconductor package may be performed along one of cutting lines CL1 and CL2, and the other side of the semiconductor package may be performed along one of cutting lines CL3 and CL4. Accordingly, three types of semiconductor packages PK1 to PK3 are obtained as shown in FIG. 5A to FIG. 5C.

As shown in FIG. 5A, one side of each semiconductor package may be performed along the cutting line CL2, and the other side of the semiconductor package may be performed along the cutting line CL3. Accordingly, each semiconductor package PK1 may have substantially straight sidewalls. In some embodiments, the semiconductor package PK1 includes an interposer 10, a semiconductor die 100 hybrid-bonded to the interposer 10 and a polymeric material P1 inserted in the non-bond region NR between the semiconductor die 100 and the interposer 10. The semiconductor package PK1 may have a symmetrical structure, and the sidewall of the polymeric material P1 is flush with the sidewall of the semiconductor die 100 and the sidewall of the interposer 10.

As shown in FIG. 5B, one side of each semiconductor package may be performed along the cutting line CL1, and the other side of the semiconductor package may be performed along the cutting line CL4. Accordingly, each semiconductor package PK1 may have substantially straight sidewalls. In some embodiments, the semiconductor package PK1 includes an interposer 10, a semiconductor die 100 hybrid-bonded to the interposer 10, a polymeric material P1 inserted in the non-bond region NR between the semiconductor die 100 and the interposer 10, and a polymeric material P2 laterally encapsulating the opposite sidewalls of the semiconductor die 100. The semiconductor package PK2 may have a symmetrical structure, and the sidewall of the polymeric material P2 is flush with the sidewall of the interposer 10.

As shown in FIG. 5C, one side of each semiconductor package may be performed along the cutting line CL2, and the other side of the semiconductor package may be performed along the cutting line CL4. Alternatively, one side of each semiconductor package may be performed along the cutting line CL1, and the other side of the semiconductor package may be performed along the cutting line CL3. Accordingly, each semiconductor package PK3 may have substantially straight sidewalls. In some embodiments, the semiconductor package PK3 includes an interposer 10, a semiconductor die 100 hybrid-bonded to the interposer 10, a polymeric material P1 inserted in the non-bond region NR between the semiconductor die 100 and the interposer 10, and a polymeric material P2 laterally encapsulating one sidewall of the semiconductor die 100. The semiconductor package PK3 may have an asymmetrical structure, in which at one side, the sidewall of the polymeric material P1 is flush with the sidewall of the semiconductor die 100 and the sidewall of the interposer 10, while at another side, the sidewall of the polymeric material P2 is flush with the sidewall of the interposer 10.

In some embodiments, the semiconductor packages PK1 to PK3 of the disclosure may stand alone as structures. In other embodiments, the semiconductor packages PK1 to PK3 of the disclosure may be bonded to another electrical component.

Referring to FIG. 4 and FIG. 5A, FIG. 5B and FIG. 5C, the wafer tape T is removed, and a board substrate 200 is formed below and electrically connected to the interposer 10. In some embodiments, the board substrate 200 is bonded to the interposer 10 through the connectors 18 and 18′.

In some embodiments, the board substrate 200 includes a core layer and two build-up layers on opposite sides of the core layer. In some embodiments, the board substrate 200 includes wiring patterns 402 that penetrate through the core layer and the build-up layers for providing electrical routing between different devices and electric components. The wiring patterns 402 include lines, vias, pads and/or connectors. The board substrate 200 is referred to as a “printed circuit board (PCB)” in some examples. In other embodiments, the core layer of the board substrate 200 may be omitted as needed, and such board substrate 200 is referred to as a “coreless board substrate”.

Thereafter, an underfill layer UF is formed to fill the space between the interposer 10 and the board substrate 200, and surrounds the connectors 18 and 18′. In some embodiments, the underfill layer UF includes a molding compound such as epoxy, and is formed using dispensing, injecting, and/or spraying process.

Afterwards, bumps or connectors 206 are formed below and electrically connected to the board substrate 200. In some embodiments, the connectors 206 are electrically to the wiring patterns 402 of the board substrate 200. In some embodiments, the connectors 206 include solder bumps, and/or may include metal pillars (e.g., copper pillars), solder caps formed on metal pillars, and/or the like. The connectors 206 are referred to as “ball grid array (BGA) balls” in some examples. The size of the connectors 206 may be different from (e.g., greater than) the size of the connectors 16 and 16′.

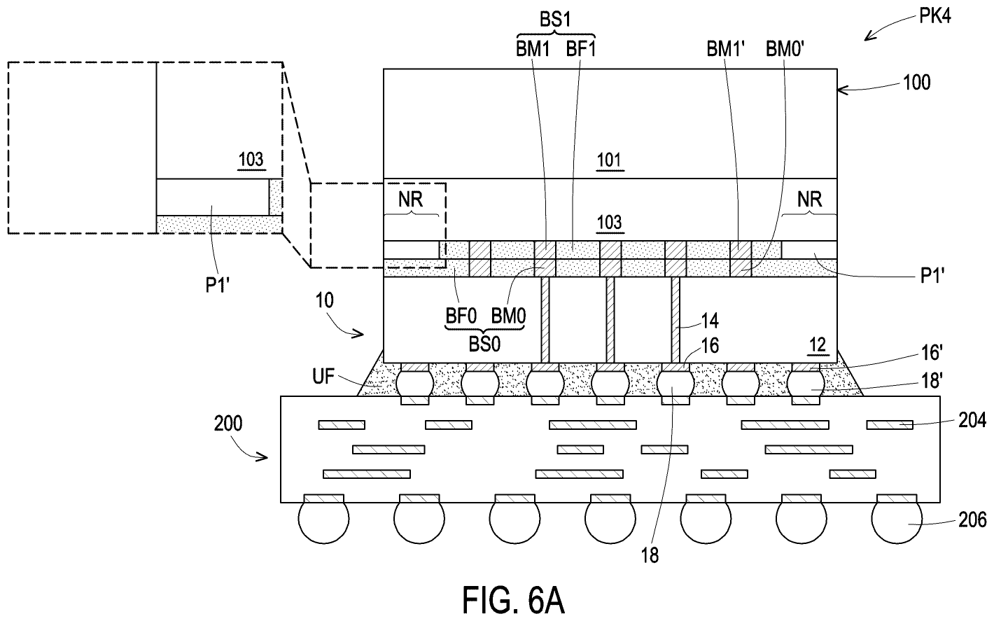

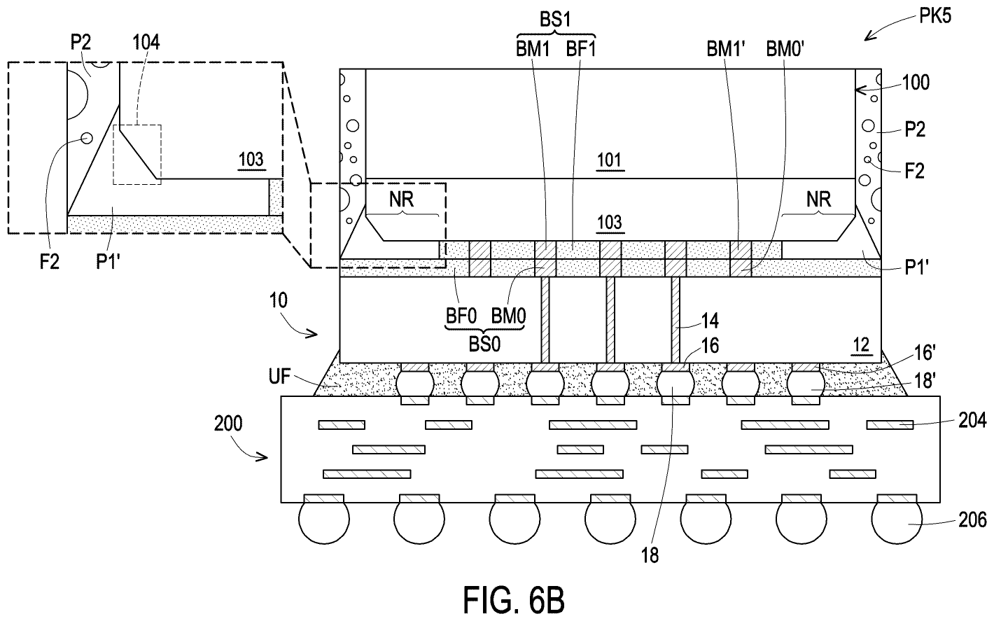

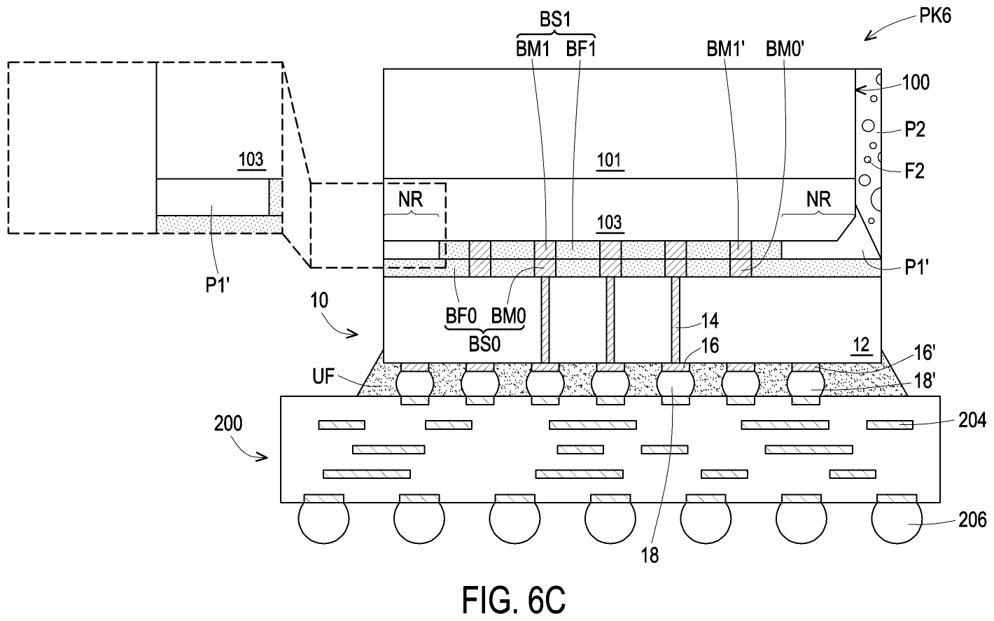

In the above embodiments, the polymeric material P1 is provided with smaller fillers (e.g., less than about 10 um), so the filling property of the polymeric material P1 is increased, and no void or less voids are present in the non-bond region NR between the semiconductor die 100 and the interposer 10. However, the disclosure is not limited thereto. In other embodiments, the polymeric material P1 may be a filler-free polymeric material, so the filling property of the polymeric material P1 is further increased, as shown in FIG. 6A to FIG. 6C.

The semiconductor package PK4 of FIG. 6A is similar to the semiconductor package PK1 of FIG. 5A, so the difference is illustrated in details below, and the similarity is not iterated herein. The difference between the semiconductor package PK4 of FIG. 6A and the semiconductor package PK1 of FIG. 5A lies in that, a filler-free polymeric material P1′ is used instead of the filler-containing polymeric material P1. In some embodiments, the polymeric material P1′ has a thixotropic index of less than about 1.5, and/or a viscosity of less than about 10 Pa·s, such that the polymeric material P1′ can fill in the non-bond region NR in an almost void-free manner. The porosity of the first polymeric material P1′ in the non-bond region NR between the semiconductor die 100 and the interposer 10 is less than about 10% or 5%. Specifically, as shown in FIG. 6A, the semiconductor package PK4 includes an interposer 10, a semiconductor die 100 hybrid-bonded to the interposer 10, and a polymeric material P1′ inserted in the non-bond region NR between the semiconductor die 100 and the interposer 10. The semiconductor package PK4 may have a symmetrical structure, and the sidewall of the polymeric material P1′ is flush with the sidewall of the semiconductor die 100 and the sidewall of the interposer 10.

The semiconductor package PK5 of FIG. 6B is similar to the semiconductor package PK2 of FIG. 5B, so the difference is illustrated in details below, and the similarity is not iterated herein. The difference between the semiconductor package PK5 of FIG. 6B and the semiconductor package PK2 of FIG. 5B lies in that, a filler-free polymeric material P1′ is used instead of the filler-containing polymeric material P1. In some embodiments, the polymeric material P1′ has a thixotropic index of less than about 1.5, and/or a viscosity of less than about 10 Pa·s, such that the polymeric material P1′ can fill in the non-bond region NR in an almost void-free manner. The porosity of the first polymeric material P1′ in the non-bond region NR between the semiconductor die 100 and the interposer 10 is less than about 10% or 5%. Specifically, as shown in FIG. 6B, the semiconductor package PK5 includes an interposer 10, a semiconductor die 100 hybrid-bonded to the interposer 10, a polymeric material P1′ inserted in the non-bond region NR between the semiconductor die 100 and the interposer 10, and a polymeric material P2 laterally encapsulating the opposite sidewalls of the semiconductor die 100. The semiconductor package PK5 may have a symmetrical structure, and the sidewall of the polymeric material P2 is flush with the sidewall of the interposer 10.

The semiconductor package PK6 of FIG. 6C is similar to the semiconductor package PK3 of FIG. 5C, so the difference is illustrated in details below, and the similarity is not iterated herein. The difference between the semiconductor package PK6 of FIG. 6C and the semiconductor package PK3 of FIG. 5C lies in that, a filler-free polymeric material P1′ is used instead of the filler-containing polymeric material P1. In some embodiments, the polymeric material P1′ has a thixotropic index of less than about 1.5, and/or a viscosity of less than about 10 Pa·s, such that the polymeric material P1′ can fill in the non-bond region NR in an almost void-free manner. The porosity of the first polymeric material P1′ in the non-bond region NR between the semiconductor die 100 and the interposer 10 is less than about 10% or 5%. Specifically, as shown in FIG. 6C, the semiconductor package PK6 includes an interposer 10, a semiconductor die 100 hybrid-bonded to the interposer 10, a polymeric material P1′ inserted in the non-bond region NR between the semiconductor die 100 and the interposer 10, and a polymeric material P2 laterally encapsulating one sidewall of the semiconductor die 100. The semiconductor package PK6 may have an asymmetrical structure, in which at one side, the sidewall of the polymeric material P1′ is flush with the sidewall of the semiconductor die 100 and the sidewall of the interposer 10, while at another side, the sidewall of the polymeric material P2 is flush with the sidewall of the interposer 10.

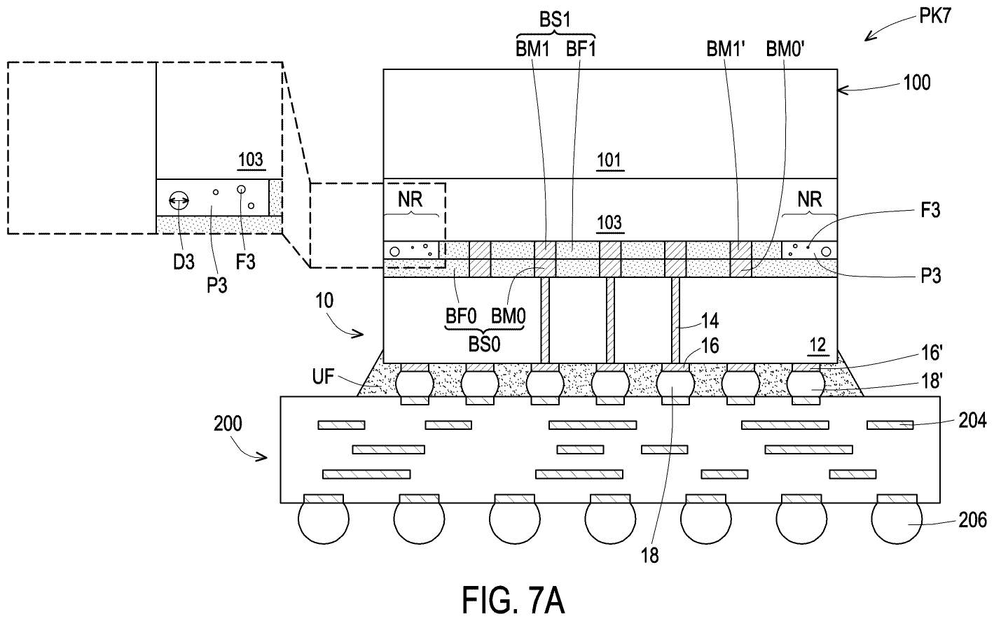

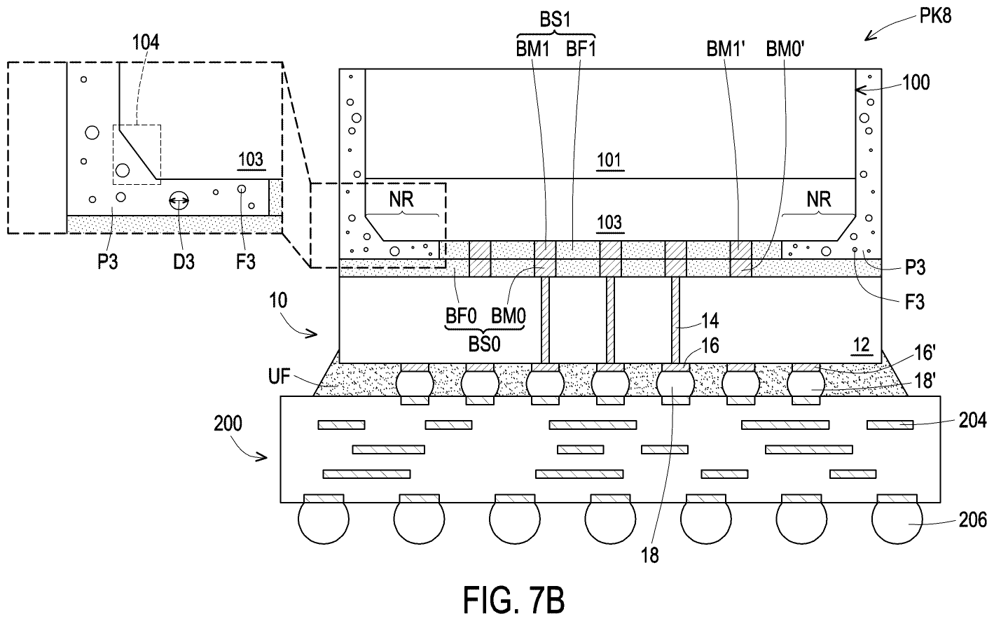

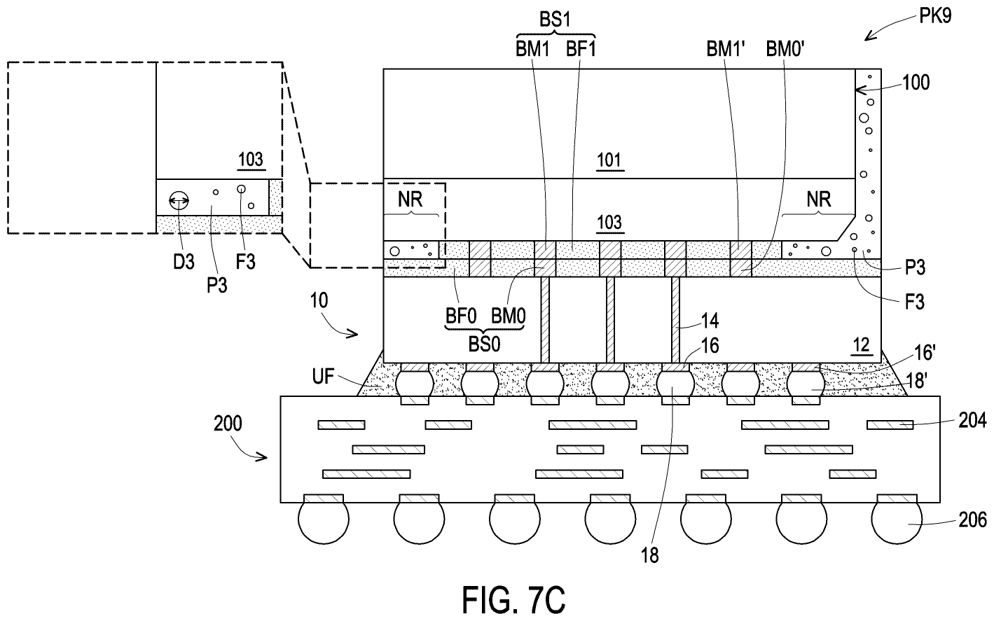

In the above embodiments, two different polymeric materials P1 and P2 are provided for different purposes. Specifically, the polymeric material P1 is provided with sufficient filling property, and the polymeric material P2 is provided with sufficient molding property. However, the disclosure is not limited thereto. In other embodiments, a single polymeric material P3 may be used, so as to simplify the process and provide sufficient filling property and molding property for the semiconductor package, as shown in FIG. 7A to FIG. 7C.

The semiconductor package PK7 of FIG. 7A is similar to the semiconductor package PK1 of FIG. 5A, so the difference is illustrated in details below, and the similarity is not iterated herein. The difference between the semiconductor package PK7 of FIG. 7A and the semiconductor package PK1 of FIG. 5A lies in that, a polymeric material P3 is used instead of the polymeric material P1. In some embodiments, the polymeric material P3 has a maximum filler size D3 of about 10 um or less (e.g., 5 um or less), a thixotropic index of less than about 1.5, and/or a viscosity of less than about 10 Pa·s, such that the polymeric material P3 can fill in the non-bond region NR in a void-free or less-void manner and provide enough molding performance. The porosity of the first polymeric material P3 is less than about 20%, 10% or 5% in the non-bond region NR between the semiconductor die 100 and the interposer 10. Specifically, as shown in FIG. 7A, the semiconductor package PK7 includes an interposer 10, a semiconductor die 100 hybrid-bonded to the interposer 10, and a polymeric material P3 inserted in the non-bond region NR between the semiconductor die 100 and the interposer 10. The semiconductor package PK7 may have a symmetrical structure, and the sidewall of the polymeric material P3 is flush with the sidewall of the semiconductor die 100 and the sidewall of the interposer 10.

The semiconductor package PK8 of FIG. 7B is similar to the semiconductor package PK2 of FIG. 5B, so the difference is illustrated in details below, and the similarity is not iterated herein. The difference between the semiconductor package PK8 of FIG. 7B and the semiconductor package PK2 of FIG. 5B lies in that, a polymeric material P3 is used instead of the polymeric materials P1 and P2. In some embodiments, the polymeric material P3 has a maximum filler size D3 of about 10 um or less (e.g., 5 um or less), a thixotropic index of less than about 1.5, and/or a viscosity of less than about 10 Pa·s, such that the polymeric material P3 can fill in the non-bond region NR in a void-free or less-void manner and provide enough molding performance. The porosity of the first polymeric material P3 is less than about 20%, 10% or 5% in the non-bond region NR between the semiconductor die 100 and the interposer 10. Specifically, as shown in FIG. 7B, the semiconductor package PK8 includes an interposer 10, a semiconductor die 100 hybrid-bonded to the interposer 10, and a polymeric material P3 inserted in the non-bond region NR between the semiconductor die 100 and the interposer 10 and laterally encapsulating the opposite sidewalls of the semiconductor die 100. The semiconductor package PK8 may have a symmetrical structure, and the sidewall of the polymeric material P3 is flush with the sidewall of the interposer 10.

The semiconductor package PK9 of FIG. 7C is similar to the semiconductor package PK3 of FIG. 5C, so the difference is illustrated in details below, and the similarity is not iterated herein. The difference between the semiconductor package PK9 of FIG. 7C and the semiconductor package PK3 of FIG. 5C lies in that, a polymeric material P3 is used instead of the polymeric materials P1 and P2. In some embodiments, the polymeric material P3 has a maximum filler size D3 of about 10 um or less (e.g., 5 um or less), a thixotropic index of less than about 1.5, and/or a viscosity of less than about 10 Pa·s, such that the polymeric material P3 can fill in the non-bond region NR in a void-free or less-void manner and provide enough molding performance. The porosity of the first polymeric material P3 is less than about 20%, 10% or 5% in the non-bond region NR between the semiconductor die 100 and the interposer 10. Specifically, as shown in FIG. 7C, the semiconductor package PK9 includes an interposer 10, a semiconductor die 100 hybrid-bonded to the interposer 10, and a polymeric material P3 inserted in the non-bond region NR between the semiconductor die 100 and the interposer 10 and laterally encapsulating one sidewall of the semiconductor die 100. The semiconductor package PK9 may have an asymmetrical structure, in which at one side, the sidewall of the polymeric material P3 is flush with the sidewall of the semiconductor die 100 and the sidewall of the interposer 10, while at another side, the sidewall of the polymeric material P3 is flush with the sidewall of the interposer 10.

The structures of the semiconductor packages of the disclosure are described below with reference to FIG. 5A to FIG. 7C.

In some embodiments, a semiconductor package PK1/PK2/PK3/PK4/PK5/PK6/PK7/PK8/PK9 includes an interposer 10, a semiconductor die 100 and a polymeric material P1/P3. The interposer 10 has an interposer bonding structure BS0 thereon, and a sidewall of the interposer bonding structure BS0 is flush with a sidewall of the interposer 10. The semiconductor die 100 has a die bonding structure BS1 thereon, and a sidewall of the die bonding structure BS1 is recessed from a sidewall of the semiconductor die 100. The semiconductor die 100 is bonded to interposer 10 through the die bonding structure BS1 and the interposer bonding structure BS0. The first polymeric material P1/P1′/P3 is disposed between the semiconductor die 100 and the interposer 10, and encompassed by the semiconductor die 100, the die bonding structure BS1 and the interposer bonding structure BS0. The porosity of the first polymeric material P1/P1′/P3 is less than about 20% in the non-bond region NR between the semiconductor die 100 and the interposer 10.

In some embodiments, a sidewall of the first polymeric material P1/P1′/P3 is flush with the sidewall of the semiconductor die 100 and the sidewall of the interposer 10. In some embodiments, the semiconductor die has a chamfer portion 104, and the first polymeric material covers P1/P1′/P3 the chamfer portion 104. In some embodiments, the first polymeric material P1/P1′/P3 has a maximum filler size of about 10 um or less (e.g., 1 to 10 um). The polymeric material P1′ is a filler-free polymeric material, so the maximum filler size is zero. In some embodiments, the first polymeric material P1 has a thixotropic index of about 1.5 or more. In some embodiments, the first polymeric material P3 has a thixotropic index of less than about 1.5. In some embodiments, the first polymeric material P1/P1′/P3 has a viscosity of less than about 10 Pa·s.

In some embodiments, the semiconductor package PK2/PK3/PK5/PK6/PK8/PK9 further includes a second polymeric material P2 disposed over the interposer 10, laterally encapsulating the semiconductor die 100 and covering the first polymeric material P1/P1′, wherein a maximum filler size of the first polymeric material P1/P1′ is less than a maximum filler size of the second polymeric material P2. In some embodiments, a thixotropic index of the first polymeric material P1/P1′ is greater than a thixotropic index of the second polymeric material P2. In some embodiments, a viscosity of the first polymeric material P1/P1′ is less than a viscosity of the second polymeric material P2.

In some embodiments, a semiconductor package PK2/PK3/PK5/PK6 includes an interposer 10, a semiconductor die 100, a first polymeric material P1/P1′ and a second polymeric material P2. The interposer 10 has an interposer bonding structure BS0 thereon, wherein the interposer includes interposer bonding metal features BM0/BM0′ embedded by an interposer bonding dielectric layer BF0. The semiconductor die 100 is bonded to the interposer 10 and has a die bonding structure BS1 thereon, wherein the die bonding structure BS1 includes die bonding metal features BM1/BM1′ embedded by a die bonding dielectric layer BF1, the interposer bonding metal features BM0/BM0′ are connected to the die bonding metal features BM1/BM1′, and the interposer bonding dielectric layer BF0 is connected to the die bonding dielectric layer BF1. The first polymeric material P1/P1′ is disposed between the semiconductor die 100 and the interposer 10 and covers a sidewall of the semiconductor die 100. The second polymeric material P2 is disposed over the interposer 10, encapsulates the sidewall of the semiconductor die 100 and covers the first polymeric material P1/P1′, wherein a maximum filler size of the first polymeric material P1/P1′ is less than a maximum filler size of the second polymeric material P2. The polymeric material P1′ is a filler-free polymeric material, so the maximum filler size is zero.

In some embodiments, a thixotropic index of the first polymeric material P1/P1′ is greater than a thixotropic index of the second polymeric material P2. In some embodiments, a viscosity of the first polymeric material P1/P1′ is less than a viscosity of the second polymeric material P2. In some embodiments, a sidewall of the second polymeric material P2 is flush with a sidewall of the interposer 10. In some embodiments, the semiconductor die 100 has a chamfer portion 104, and the first polymeric material P1/P1′ covers the chamfer portion 104. In some embodiments, the semiconductor package further includes a board substrate 200 bonded to the interposer 10, wherein the board substrate 200 and the semiconductor die 100 are disposed at opposite sides of the interposer 10.

In view of above, in the disclosure, the non-bond region between the die and the interposer around the chamfer portion is first filled with a polymeric material with a smaller filler size, a lower viscosity and/or a higher thixotropic index, so as to improve the filling performance in the non-bond region between the die and the interposer around the chamfer portion. Thereafter, another polymeric material with a greater filler size, a higher viscosity and/or a lower thixotropic index is formed to encapsulate the die, so as to robust the package. By such manner, the bonding performance is improved and the package stiffness is obtained.

Many variations of the above examples are contemplated by the disclosure. It is understood that different embodiments may have different advantages, and that no particular advantage is necessarily required of all embodiments.

In accordance with some embodiments of the disclosure, a semiconductor package includes an interposer, a semiconductor die and a first polymeric material. The interposer has an interposer bonding structure thereon, and a sidewall of the interposer bonding structure is flush with a sidewall of the interposer. The semiconductor die has a die bonding structure thereon, and a sidewall of the die bonding structure is recessed from a sidewall of the semiconductor die. The semiconductor die is bonded to interposer through the die bonding structure and the interposer bonding structure. The first polymeric material is disposed in a non-bond region between the semiconductor die and the interposer, and encompassed by the semiconductor die, the die bonding structure and the interposer bonding structure. The porosity of the first polymeric material is less than about 20% in the non-bond region between the semiconductor die and the interposer.

In accordance with some embodiments of the disclosure, a semiconductor package includes an interposer, a semiconductor die, a first polymeric material and a first polymeric material. The interposer has an interposer bonding structure thereon, wherein the interposer includes interposer bonding metal features embedded by an interposer bonding dielectric layer. The semiconductor die is bonded to the interposer and has a die bonding structure thereon, wherein the die bonding structure includes die bonding metal features embedded by a die bonding dielectric layer, the interposer bonding metal features are connected to the die bonding metal features, and the interposer bonding dielectric layer is connected to the die bonding dielectric layer. The first polymeric material is disposed between the semiconductor die and the interposer and covers a sidewall of the semiconductor die. The second polymeric material is disposed over the interposer, encapsulates the sidewall of the semiconductor die and covers the first polymeric material, wherein a maximum filler size of the first polymeric material is less than a maximum filler size of the second polymeric material.

In accordance with some embodiments of the disclosure, a method of forming a semiconductor package includes the following operations. An interposer is provided with an interposer bonding structure thereon, wherein the interposer includes interposer bonding metal features embedded by an interposer bonding dielectric layer. At least one semiconductor die is provided with a die bonding structure thereon, wherein the die bonding structure includes die bonding metal features embedded by a die bonding dielectric layer, and a sidewall of the die bonding structure is recessed from a sidewall of the semiconductor die. The semiconductor die is bonded to the interposer with the interposer bonding metal features connected to the die bonding metal features and the interposer bonding dielectric layer connected to the die bonding dielectric layer, such that a space is formed between the semiconductor die and the interposer. The space is filled with a first polymeric material. The semiconductor die is encapsulated with a second polymeric material, wherein a maximum filler size of the first polymeric material is less than a maximum filler size of the second polymeric material.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor package, comprising:
an interposer having an interposer bonding structure thereon, wherein a sidewall of the interposer bonding structure is flush with a sidewall of the interposer;
a semiconductor die having a die bonding structure thereon, wherein a sidewall of the die bonding structure is recessed from a sidewall of the semiconductor die, and the semiconductor die is bonded to interposer through the die bonding structure and the interposer bonding structure; and
a first polymeric material disposed in a non-bond region between the semiconductor die and the interposer, and encompassed by the semiconductor die, the die bonding structure and the interposer bonding structure, wherein a porosity of the first polymeric material is less than about 20% in the non-bond region between the semiconductor die and the interposer.

2. The semiconductor package of claim 1, wherein a sidewall of the first polymeric material is flush with the sidewall of the semiconductor die and the sidewall of the interposer.

3. The semiconductor package of claim 1, wherein the semiconductor die has a chamfer portion, and the first polymeric material covers the chamfer portion.

4. The semiconductor package of claim 1, wherein the first polymeric material has a maximum filler size of about 10 um or less.

5. The semiconductor package of claim 1, wherein the first polymeric material has a thixotropic index of about 1.5 or more.

6. The semiconductor package of claim 1, wherein the first polymeric material has a viscosity of less than about 10 Pa·s.

7. The semiconductor package of claim 1, further comprising a second polymeric material disposed over the interposer, laterally encapsulating the semiconductor die and covering the first polymeric material, wherein a maximum filler size of the first polymeric material is less than a maximum filler size of the second polymeric material.

8. The semiconductor package of claim 7, wherein a thixotropic index of the first polymeric material is greater than a thixotropic index of the second polymeric material.

9. The semiconductor package of claim 7, wherein a viscosity of the first polymeric material is less than a viscosity of the second polymeric material.

10. A semiconductor package, comprising:
an interposer having an interposer bonding structure thereon, wherein the interposer comprises interposer bonding metal features embedded by an interposer bonding dielectric layer;
a semiconductor die bonded to the interposer and having a die bonding structure thereon, wherein the die bonding structure comprises die bonding metal features embedded by a die bonding dielectric layer, the interposer bonding metal features are connected to the die bonding metal features, and the interposer bonding dielectric layer is connected to the die bonding dielectric layer;
a first polymeric material disposed between the semiconductor die and the interposer and covering a sidewall of the semiconductor die; and
a second polymeric material disposed over the interposer, encapsulating the sidewall of the semiconductor die and covering the first polymeric material, wherein a maximum filler size of the first polymeric material is less than a maximum filler size of the second polymeric material.

11. The semiconductor package of claim 10, wherein a thixotropic index of the first polymeric material is greater than a thixotropic index of the second polymeric material.

12. The semiconductor package of claim 10, wherein a viscosity of the first polymeric material is less than a viscosity of the second polymeric material.

13. The semiconductor package of claim 10, wherein a sidewall of the second polymeric material is flush with a sidewall of the interposer.

14. The semiconductor package of claim 10, wherein the semiconductor die has a chamfer portion, and the first polymeric material covers the chamfer portion.

15. The semiconductor package of claim 10, further comprising a board substrate bonded to the interposer, wherein the board substrate and the semiconductor die are disposed at opposite sides of the interposer.

16. A method of forming a semiconductor package, comprising:
providing an interposer having an interposer bonding structure thereon, wherein the interposer comprises interposer bonding metal features embedded by an interposer bonding dielectric layer;
providing at least one semiconductor die having a die bonding structure thereon, wherein the die bonding structure comprises die bonding metal features embedded by a die bonding dielectric layer, and a sidewall of the die bonding structure is recessed from a sidewall of the semiconductor die;
bonding the semiconductor die to the interposer with the interposer bonding metal features connected to the die bonding metal features and the interposer bonding dielectric layer connected to the die bonding dielectric layer, such that a space is formed between the semiconductor die and the interposer;
filling the space with a first polymeric material; and
encapsulating the semiconductor die with a second polymeric material, wherein a maximum filler size of the first polymeric material is less than a maximum filler size of the second polymeric material.

17. The method of claim 16, wherein a thixotropic index of the first polymeric material is greater than a thixotropic index of the second polymeric material.

18. The method of claim 16, wherein a viscosity of the first polymeric material is less than a viscosity of the second polymeric material.

19. The method of claim 16, further comprising cutting the semiconductor die, the first polymeric material and the interposer along a cutting line.

20. The method of claim 16, further comprising bonding the interposer to a board substrate, wherein the board substrate and the semiconductor die are at opposite sides of the interposer.
